(19) United States
(12) Patent Application Publication
(10) Pub. No.: US 2022/0293630 A1
(43) Pub. Date: Sep. 15, 2022

(54) SEMICONDUCTOR MEMORY DEVICE

(71) Applicant: Kioxia Corporation, Tokyo (JP)

(72) Inventors: Koki MATOBA, Yokkaichi (JP); Hiroaki NAITO, Yokkaichi (JP)

(73) Assignee: Kioxia Corporation, Tokyo (JP)

(21) Appl. No.: 17/473,277

(22) Filed: Sep. 13, 2021

(30) Foreign Application Priority Data
Mar. 12, 2021 (JP) 2021-040527

(51) Int. Cl. H01L 27/11582; H01L 27/11556

(52) U.S. Cl. CPC H01L 27/11582; H01L 27/11556

(57) ABSTRACT

A semiconductor memory device includes a plurality of first conductive layers, a first semiconductor layer opposed to them, a first insulating film disposed between the plurality of first conductive layers and the first semiconductor layer, a second semiconductor layer connected to the first semiconductor layer, a second conductive layer opposed to this, a second insulating film disposed between the second semiconductor layer and the second conductive layer, and a third semiconductor layer connected to the first semiconductor layer via the second semiconductor layer. The second conductive layer includes a first part and a second part disposed between the first part and the second semiconductor layer. A thickness in the first direction of the second part is smaller than a thickness in the first direction of the first part.

### CROSS-REFERENCE TO RELATED APPLICATIONS

This application is based upon and claims the benefit of Japanese Patent Application No. 2021-040527, filed on Mar. 12, 2021, the entire contents of which are incorporated herein by reference.

### BACKGROUND

### Field

Embodiments described herein relate generally to a semiconductor memory device.

### Description of the Related Art

There has been known a semiconductor memory device that includes a substrate, a plurality of conductive layers stacked in a direction intersecting with a surface of the substrate, a semiconductor layer opposed to the plurality of conductive layers, agate insulating layer disposed between the plurality of conductive layers and the semiconductor layer. The gate insulating layer includes a memory unit configured to store data. The memory unit is, for example, an insulating electric charge accumulating layer of silicon nitride (SiN) or the like and a conductive electric charge accumulating layer, such as a floating gate, or the like.

### BRIEF DESCRIPTION OF THE DRAWINGS

FIG. 1 is a schematic circuit diagram illustrating a part of a configuration of a semiconductor memory device according to a first embodiment;

FIG. 2 is a schematic perspective view illustrating a part of the configuration of the semiconductor memory device;

FIG. 3 is a schematic cross-sectional view illustrating an enlarged view of a part indicated by A in the structure illustrated in FIG. 2;

FIG. 4 is a schematic cross-sectional view illustrating an enlarged view of a part indicated by B in the structure illustrated in FIG. 2;

FIG. 5 is a schematic cross-sectional view for describing a manufacturing method of the semiconductor memory device according to the first embodiment;

FIG. 6 is a schematic cross-sectional view for describing the manufacturing method;

FIG. 7 is a schematic cross-sectional view for describing the manufacturing method;

FIG. 8 is a schematic cross-sectional view for describing the manufacturing method;

FIG. 9 is a schematic cross-sectional view for describing the manufacturing method;

FIG. 10 is a schematic cross-sectional view for describing the manufacturing method;

FIG. 11 is a schematic cross-sectional view for describing the manufacturing method;

FIG. 12 is a schematic cross-sectional view for describing the manufacturing method;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view illustrating a part of a configuration of a semiconductor memory device according to a comparative example; and

FIG. 18 is a schematic perspective view illustrating a part of a configuration of a semiconductor memory device according to another embodiment.

### DETAILED DESCRIPTION

A semiconductor memory device according to one embodiment comprises: a plurality of first conductive layers arranged in a first direction, the plurality of first conductive layers extending in a second direction intersecting with the first direction; a first semiconductor layer extending in the first direction and being opposed to the plurality of first conductive layers; and a first insulating film disposed between the plurality of first conductive layers and the first semiconductor layer, the first insulating film including an electric charge accumulating portion. The semiconductor memory device comprises a second semiconductor layer connected to one end in the first direction of the first semiconductor layer; a second conductive layer extending in the second direction and being opposed to the second semiconductor layer; a second insulating film disposed between the second conductive layer and the second semiconductor layer; and a third semiconductor layer extending in the second direction and being connected to the first semiconductor layer via the second semiconductor layer. The second conductive layer includes: a first part extending in the second direction; and a second part disposed between the first part and the second semiconductor layer. When a thickness in the first direction of the first part is assumed to be a first thickness, and a thickness in the first direction of the second part is assumed to be a second thickness, the second thickness is smaller than the first thickness.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to “semiconductor memory device,” it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when referring to that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in OFF state, the first transistor is “electrically connected” to the third transistor.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion at a side opposite to the substrate of this configuration. A surface intersecting with the X-direction or the Y-direction is referred to as a side surface and the like.

In this specification, when referring to a “width,” a “length,” a “thickness,” or the like in a predetermined direction of a configuration, a member, or the like, this may mean a width, a length, a thickness, or the like in a cross-sectional surface or the like observed with a Scanning electron microscopy (SEM), a Transmission electron microscopy (TEM), or the like.

### First Embodiment

[Configuration]

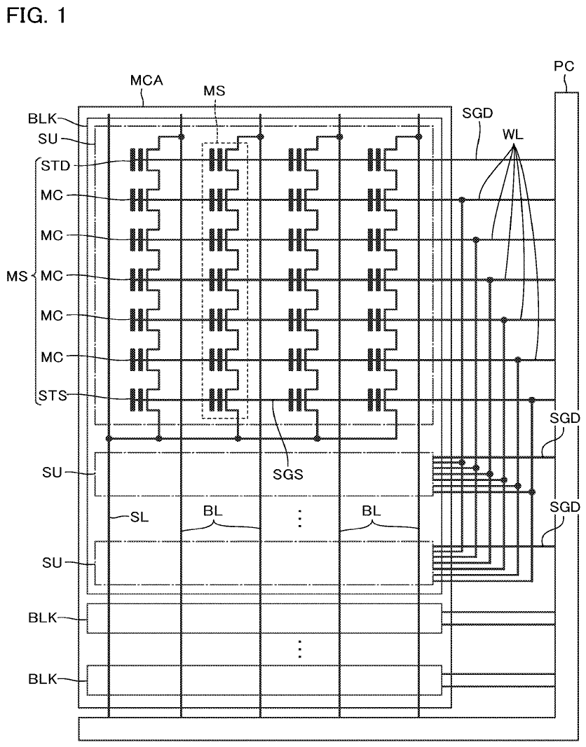

FIG. 1 is a schematic circuit diagram illustrating a part of a configuration of a semiconductor memory device according to the first embodiment. The semiconductor memory device according to the first embodiment includes a memory cell array MCA and a peripheral circuit PC.

The memory cell array MCA includes a plurality of memory blocks BLK. The plurality of memory blocks BLK each include a plurality of string units SU. The plurality of string units SU each include a plurality of memory strings MS. The plurality of memory strings MS have one ends each connected to the peripheral circuit PC via a bit line BL. The plurality of memory strings MS have other ends each connected to the peripheral circuit PC via a common source line SL.

The memory string MS includes a drain-side select transistor STD, a plurality of memory cells MC (memory transistors), and a source-side select transistor STS. The drain-side select transistor STD, a plurality of memory cells MC, and a source-side select transistor STS are connected in series between the bit line BL and the source line SL. Hereinafter, the drain-side select transistor STD and the source-side select transistor STS may be simply referred to as select transistors (STD, STS).

The memory cell MC is a field-effect type transistor. The memory cell MC includes a semiconductor layer, agate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC stores one bit or a plurality of bits of data. Word lines WL are connected to the respective gate electrodes of the plurality of memory cells MC corresponding to one memory string MS. These respective word lines WL are connected to all of the memory strings MS in one memory block BLK in common.

The select transistor (STD, STS) is a field-effect type transistor. The select transistor (STD, STS) includes a semiconductor layer, a gate insulating film, and a gate electrode. The semiconductor layer functions as a channel region. The select gate lines (SGD, SGS) are connected to the respective gate electrodes of the select transistors (STD, STS). One drain-side select gate line SGD is connected to all the memory strings MS in one string unit SU in common. One source-side select gate line SGS is connected to all the memory strings MS in one memory block BLK in common.

The peripheral circuit PC includes, for example, a voltage generation circuit that generates an operating voltage, a voltage transfer circuit that transfers the generated operating voltage to, for example, the selected bit line BL, word line WL, source line SL, select gate lines (SGD, SGS), and the like, a sense amplifier module connected to the bit line BL, and a sequencer that controls them.

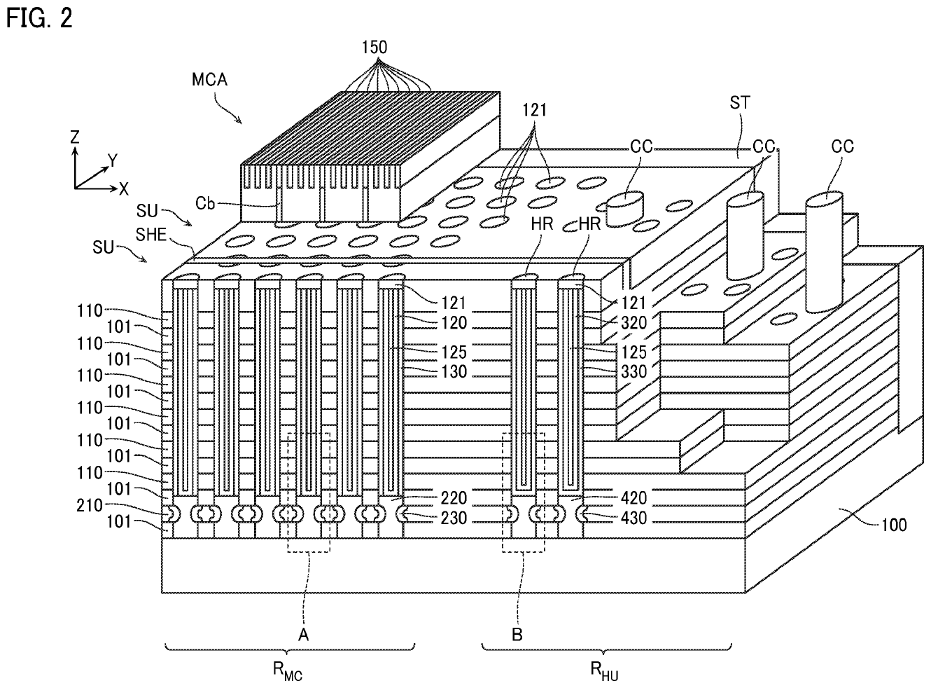

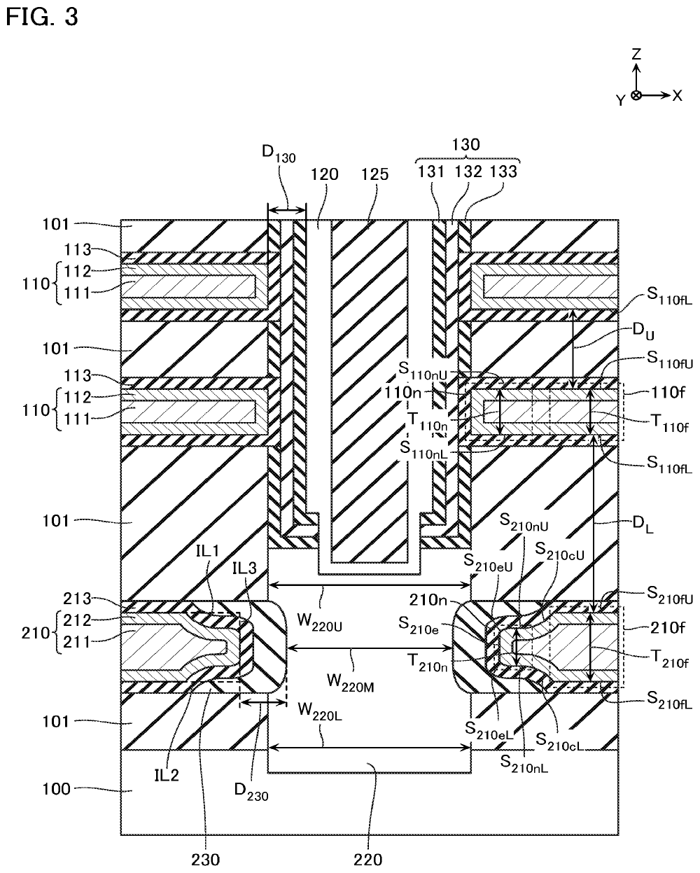

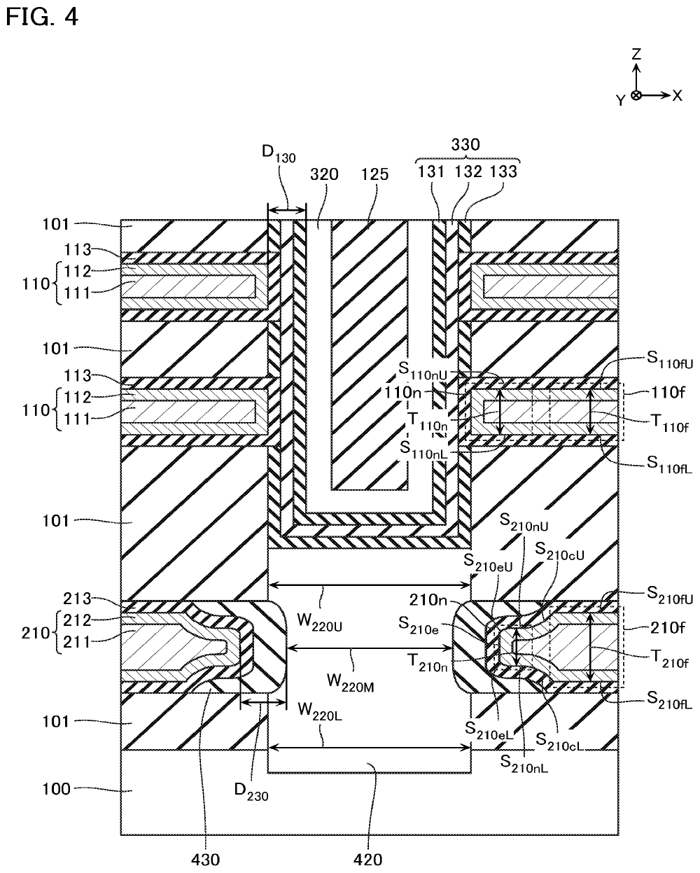

FIG. 2 is a schematic perspective view illustrating apart of the configuration of the semiconductor memory device according to the first embodiment. FIG. 3 is a schematic cross-sectional view illustrating an enlarged view of a part indicated by A in the structure illustrated in FIG. 2. FIG. 4 is a schematic cross-sectional view illustrating an enlarged view of a part indicated by B in the structure illustrated in FIG. 2. While FIG. 3 indicates an XZ cross-sectional surface, when other cross-sectional surfaces along a center axis of a semiconductor layer 120 other than the XZ cross-sectional surface (for example, a YZ cross-sectional surface) is observed, a structure similar to FIG. 3 is observed. Similarly, while FIG. 4 indicates an XZ cross-sectional surface, when other cross-sectional surfaces along a center axis of a semiconductor layer 320 other than the XZ cross-sectional surface (for example, a YZ cross-sectional surface) is observed, a structure similar to FIG. 4 is observed.

As illustrated in FIG. 2, the semiconductor memory device according to the embodiment includes a semiconductor substrate 100. The semiconductor substrate 100 has a surface layer where, for example, a semiconductor layer made of P-type silicon (Si) containing P-type impurities, such as boron (B), is disposed. A memory cell region R_{MC} and a hook-up region R_{HU} are disposed in the semiconductor substrate 100.

As illustrated in FIG. 2, in the memory cell region R_{MC} of the semiconductor memory device according to the embodiment, a plurality of conductive layers 110 arranged in the Z direction, a plurality of semiconductor layers 120 opposed to the plurality of conductive layers 110, and a plurality of insulating layers 130 disposed between the plurality of conductive layers 110 and the plurality of semiconductor layers 120 are disposed. In the memory cell region R_{MC}, a conductive layer 210 disposed between the semiconductor substrate 100 and the plurality of conductive layers 110, a plurality of semiconductor layers 220 opposed to the conductive layer 210, and a plurality of insulating layers 230 disposed between the conductive layer 210 and the plurality of semiconductor layers 220 are disposed.

The conductive layer 110 is an approximately plate-shaped conductive layer extending in the X direction. For example, as illustrated in FIG. 3, the conductive layer 110 includes a metal film 111 of tungsten (W) or the like, and a barrier conductive film 112 of titanium nitride (TiN) or the like that covers an upper surface and a lower surface and side surfaces in the X direction and the Y direction of the metal film 111. The conductive layer 110 may include, for example, a polycrystalline silicon or the like containing impurities, such as phosphorus (P) or boron (B). Between the plurality of conductive layers 110 arranged in the Z direction, insulating layers 101 of silicon oxide (SiO₂) or the like are disposed.

One or a plurality of conductive layers 110 positioned uppermost functions as the drain-side select gate line SGD (FIG. 1) and the gate electrodes of the plurality of drain-side select transistors STD (FIG. 1) connected to the drain-side select gate line SGD. The conductive layer 110 that functions as the drain-side select gate line SGD (FIG. 1) or the like is arranged in the Y direction via an inter-string unit insulating layer SHE (FIG. 2) of silicon oxide (SiO₂) or the like or an inter-finger insulating layer ST (FIG. 2) of silicon oxide (SiO₂).

A plurality of conductive layers 110 positioned below these function as the word lines WL (FIG. 1) and the gate electrodes of the plurality of memory cells MC (FIG. 1) connected to the word lines WL. The conductive layer 110 that functions as the word line WL (FIG. 1) or the like has a width in the Y direction larger than that of the conductive layer 110 that functions as the drain-side select gate line SGD (FIG. 1) or the like. The conductive layers 110, which function as the word lines WL (FIG. 1) or the like, are arranged in the Y direction via the inter-finger insulating layers ST (FIG. 2).

An insulating layer 113 (FIG. 3) may be disposed on the upper and lower surfaces and the side surfaces in the X direction and the Y direction of the conductive layer 110. The insulating layer 113 includes, for example, an insulating metal oxide such as alumina (Al₂O₃). The insulating layer 113, for example, functions as a part of the gate insulating film of the memory cell MC (FIG. 1) or the drain-side select transistor STD (FIG. 1).

For example, as illustrated in FIG. 2, the semiconductor layers 120 are arranged in a predetermined pattern in the X direction and the Y direction. The semiconductor layers 120 function as the channel regions of the plurality of memory cells MC (FIG. 1) and the drain-side select transistors STD (FIG. 1) included in one memory string MS (FIG. 1). The semiconductor layer 120 includes, for example, polycrystalline silicon (Si) or the like. The semiconductor layer 120 has an approximately closed-bottomed cylindrical shape, and an insulating layer 125 of silicon oxide or the like is disposed in the center portion. The respective outer peripheral surface of the semiconductor layers 120 are surrounded by the conductive layers 110 and are opposed to the conductive layers 110.

The semiconductor layer 120 has an upper end portion where an impurity region 121 containing N-type impurities such as phosphorus (P) is disposed. The impurity region 121 is connected to a conductive layer 150 via a contact electrode Cb. The conductive layers 150 extend in the Y direction and are arranged in the X direction. The conductive layer 150 functions as the bit line BL (FIG. 1). A lower end portion of the semiconductor layer 120 is connected to the semiconductor layer 220.

The insulating layer 130 has an approximately cylindrical shape covering the outer peripheral surface of the semiconductor layer 120. The insulating layer 130 has a lower end connected to the upper surface of the semiconductor layer 220. The insulating layer 130 functions as parts of the gate insulating films of the plurality of memory cells MC (FIG. 1) and the drain-side select transistor STD (FIG. 1) included in one memory string MS (FIG. 1).

For example, as illustrated in FIG. 3, the insulating layer 130 includes a tunnel insulating film 131 disposed on the outer peripheral surface of the semiconductor layer 120, an electric charge accumulating film 132 disposed on the outer peripheral surface of the tunnel insulating film 131, and an insulating film 133 disposed on the outer peripheral surface of the electric charge accumulating film 132. The tunnel insulating film 131 and the insulating film 133 are, for example, insulating films of silicon oxide (SiO₂) or the like. The electric charge accumulating film 132 is, for example, an insulating film of silicon nitride (SiN), which is capable of accumulating charges. The tunnel insulating film 131 and the electric charge accumulating film 132 have approximately cylindrical shapes and extend in the Z direction along the outer peripheral surface of the semiconductor layer 120. The insulating film 133, as illustrated in the drawing, may be separated into a plurality of portions arranged in the Z direction corresponding to the insulating layer 101 or may be extended in the Z direction similarly to the tunnel insulating film 131 and the electric charge accumulating film 132.

In FIG. 3, there is illustrated an example where the insulating layer 130 includes the insulating electric charge accumulating film 132 of silicon nitride or the like. However, for example, instead of the electric charge accumulating film 132, the insulating layer 130 may include a plurality of floating gates arranged in the Z direction corresponding to the conductive layers 110. The floating gate may include, for example, the polycrystalline silicon or the like. In this case, the polycrystalline silicon in the floating gate may include the impurities such as phosphorus (P) or boron (B) or is not required to include the impurities.

The conductive layer 210 is an approximately plate-shaped conductive layer extending in the X direction. For example, as illustrated in FIG. 3, the conductive layer 210 includes a metal film 211 of tungsten (W) or the like and a barrier conductive film 212 of titanium nitride (TiN) or the like covering an upper surface and a lower surface and side surfaces in the X direction and the Y direction of the metal film 211. The conductive layer 210 may include, for example, polycrystalline silicon containing the impurities such as phosphorus (P) or boron (B), or the like. The insulating layers 101 of silicon oxide (SiO₂) are disposed above and below the conductive layer 210.

The conductive layer 210 functions as the source-side select gate line SGS (FIG. 1) and the gate electrodes of the plurality of source-side select transistors STS (FIG. 1) connected thereto.

An insulating layer 213 may be disposed on the upper and lower surfaces and the side surfaces in the X direction and the Y direction of the conductive layer 210. The insulating layer 213 includes, for example, an insulating metal oxide such as alumina (Al₂O₃). The insulating layer 213 functions as, for example, a part of the gate insulating film of the source-side select transistor STS (FIG. 1).

In FIG. 3, a part of the conductive layer 210 where a distance from the semiconductor layer 220 is outside a predetermined range is indicated as a part 210f. In addition, a part of the conductive layer 210 where a distance from the semiconductor layer 220 is within the predetermined range is indicated as a part 210n. A thickness T₂₁₀ₙ in the Z direction of the part 210n is smaller than a thickness T_{210f} in the Z direction of the part 210f.

An upper surface S_{210nU} of the part 210n is positioned below an upper surface S_{210fU} of the part 210f. The upper surface S_{210nU} is continuously formed with a recessed curved surface S_{210cU} The upper surface S_{210nU} is connected to the upper surface S_{210fU} via the recessed curved surface S_{210cU}. The upper surface S_{210nU} is continuously formed with a projecting curved surface S_{210eU} The upper surface S_{210nU} is connected to an opposed surface S₂₁₀ₑ to the semiconductor layer 220 via the projecting curved surface S_{210eU}.

For example, when assuming an imaginary line IL1 that extends in the X direction along the upper surface S_{210fU} of the part 210f, a distance of each point constituting the upper surface S_{210fU} from the imaginary line IL1 may be approximately zero. In addition, a magnitude of an inclination in the XZ cross-sectional surface of the curved surface S_{210cU} may be monotonously reduced as approaching the opposed surface S₂₁₀ₑ. A distance of each point constituting the upper surface S_{210nU} of the part 210n from the imaginary line IL1 may be approximately constant or may be monotonously increased as approaching the opposed surface S₂₁₀ₑ. A magnitude of an inclination in the XZ cross-sectional surface of the curved surface S_{210eU} may be monotonously increased as approaching the opposed surface S₂₁₀ₑ.

A lower surface S_{210nL} of the part 210n is positioned above a lower surface S_{210fL} of the part 210f. The lower surface S_{210fL} is continuously formed with a recessed curved surface S_{210cL}. The lower surface S_{210nL} is connected to the lower surface S_{210fL} via the recessed curved surface S_{210cL}. The lower surface S_{210nL} is continuously formed with a projecting curved surface S_{210eL} The lower surface S_{210nL} is connected to the opposed surface S₂₁₀ₑ to the semiconductor layer 220 via the projecting curved surface S_{210eL}.

For example, when assuming an imaginary line IL2 that extends in the X direction along the lower surface S_{210fL} of the part 210f, a distance of each point constituting the lower surface S_{210fL} from the imaginary line IL2 may be approximately zero. In addition, a magnitude of an inclination in the XZ cross-sectional surface of the curved surface S_{210cL} may be monotonously reduced as approaching the opposed surface S₂₁₀ₑ. A distance of each point constituting the lower surface S_{210nL} of the part 210n from the imaginary line IL2 may be approximately constant or may be monotonously increased as approaching the opposed surface S₂₁₀ₑ. A magnitude of an inclination in the XZ cross-sectional surface of the curved surface S_{210eL} may be monotonously increased as approaching the opposed surface S₂₁₀ₑ.

Furthermore, for example, when assuming an imaginary line IL3 that extends in the Z direction along the opposed surface S₂₁₀ₑ to the semiconductor layer 220 of the conductive layer 210, a distance of each point constituting the opposed surface S₂₁₀ₑ from the imaginary line IL3 may be approximately zero.

The opposed surface S₂₁₀ₑ to the semiconductor layer 220 of the conductive layer 210 is not required to be flat in the XZ cross-sectional surface. In this case, the above-described curved surfaces S_{210eU} and S_{210eL} may be connected one another. In addition, the curved surfaces S_{210eU} and S_{210eL} may be partially opposed to the semiconductor layer 220.

In FIG. 3, a part of the conductive layers 110 where a distance from the semiconductor layer 120 is outside a predetermined range is indicated as a part 110f. In addition, a part of the conductive layers 110 where a distance from the semiconductor layer 120 is within the predetermined range is indicated as a part 110n. The part 110f is aligned with the part 210f in the Z direction. The part 110n is aligned with the part 210n in the Z direction.

A thickness T₁₁₀ₙ in the Z direction of the part 110n is same extent as a thickness T_{110f} in the Z direction of the part 110f. At least, a difference between the thickness T₂₁₀ₙ and the thickness T_{210f} is larger than a difference between the thickness T₁₁₀ₙ and the thickness T_{110f}.

A height position of an upper surface S_{110nU} of the part 110n is same extent as a height position of an upper surface S_{110fU} of the part 110f. At least, a difference between a height position of the upper surface S_{210nU} and a height position of the upper surface S_{210fU} is larger than a difference between the height position of the upper surface S_{110nU} and the height position of the upper surface S_{110fU}.

A height position of a lower surface S_{110nL} of the part 110n is same extent as a height position of a lower surface S_{110fL} of the part 110f. At least, a difference between a height position of the lower surface S_{210nL} and a height position of the lower surface S_{210fL} is larger than a difference between the height position of the lower surface S_{110nL} and the height position of the lower surface S_{110fL}.

Furthermore, a distance D_{L} between the upper surface S_{210fU} of the conductive layer 210 and the lower surface S_{110fL} of the conductive layer 110 positioned at a lowermost position is larger than a distance Dᵤ between an upper surface S_{110fU} of one of the conductive layers 110 and a lower surface S_{110fL} of another of the conductive layers 110 which is disposed above the one conductive layer 110 and adjacent to the one conductive layer 110 in the Z direction.

The semiconductor layers 220 are arranged in the X direction and the Y direction in a predetermined pattern corresponding to the semiconductor layers 120. The semiconductor layers 220 function as the channel regions of the source-side select transistors STS. The semiconductor layer 220 includes, for example, single-crystal silicon (Si) or the like. An orientation face of the silicon crystal included in the semiconductor layer 220 may be aligned with the orientation face of the silicon crystal included in the semiconductor substrate 100. The respective outer peripheral surfaces of the semiconductor layers 220 are surrounded by the conductive layer 210 and are opposed to the conductive layer 210.

In FIG. 3, a width in the X direction of a portion of the semiconductor layer 220 disposed below a contact area with the insulating layer 230, is indicated as a width W_{220L} In addition, in FIG. 3, a width of a portion of the semiconductor layer 220 disposed at a height position corresponding to a center position in the Z direction of the conductive layer 210, is indicated as a width W_{220M}. Furthermore, in FIG. 3, a width in the X direction of a portion of the semiconductor layer 220 disposed above the contact area with the insulating layer 230, is indicated as a width W_{220U} The width W_{220M} is smaller than the width W_{220L}. The width W_{220M} is smaller than the width W_{220U}.

The insulating layer 230 is disposed on a part of the outer peripheral surface of the semiconductor layer 220. The insulating layer 230 covers an upper surface and a lower surface, and side surfaces in the X direction and the Y direction of the part 210n of the conductive layer 210 via the insulating layer 213. The insulating layer 230 functions as a part of the gate insulating film of the source-side select transistor STS (FIG.

In addition, in FIG. 3, a distance between the conductive layer 110 and the semiconductor layer 120 is indicated as a distance D₁₃₀. Furthermore, a distance between the conductive layer 210 and the semiconductor layer 220 is indicated as a distance D₂₃₀. The distance D₂₃₀ is larger than the distance D₁₃₀.

As illustrated in FIG. 2, in the hook-up region R_{HU} of the semiconductor memory device according to the embodiment, parts of the plurality of conductive layers 110, contact electrodes CC connected to the plurality of conductive layers 110, and a plurality of supporting structures HR disposed at the proximity of the contact electrodes CC are disposed. The respective supporting structure HR include the semiconductor layer 320 opposed to the plurality of conductive layers 110 and an insulating film 330 disposed between the plurality of conductive layers 110 and the semiconductor layer 320. Furthermore, the hook-up region R_{HU} is provided with a part of the conductive layer 210, a plurality of semiconductor layers 420 opposed to the conductive layer 210, and a plurality of insulating layers 430 disposed between the conductive layer 210 and the plurality of semiconductor layers 420.

The contact electrode CC extends in the Z direction to be connected to any of the conductive layers 110 at its lower end. The contact electrode CC includes, for example, a barrier conductive film of titanium nitride (TiN) or the like and a metal film of tungsten (W) or the like.

The semiconductor layer 320 is basically configured similarly to the semiconductor layer 120. However, the upper end of the semiconductor layer 320 is not connected to the bit line BL. In addition, for example, as illustrated in FIG. 4, the lower end of the semiconductor layer 320 is covered by the insulating film 330 and is not connected to the semiconductor layer 420. The semiconductor layer 320 does not function as parts of transistors or the like.

The insulating film 330 is basically configured similarly to the insulating layer 130. However, the insulating film 330 does not function as parts of transistors or the like.

The semiconductor layer 420 is basically configured similarly to the semiconductor layer 220. However, the semiconductor layer 420 does not function as parts of transistors or the like.

The insulating layer 430 is basically configured similarly to the insulating layer 230. However, the insulating layer 430 does not function as parts of transistors or the like. In addition, in a portion of the conductive layer 210 where a distance from the semiconductor layer 420 is within a predetermined range, the part 210n as described above is disposed.

[Manufacturing Method]

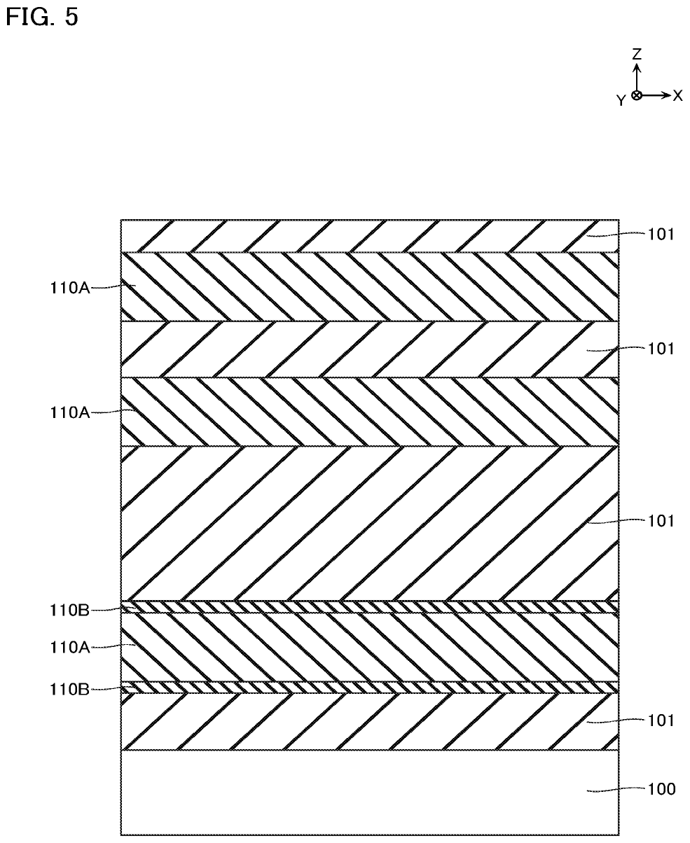

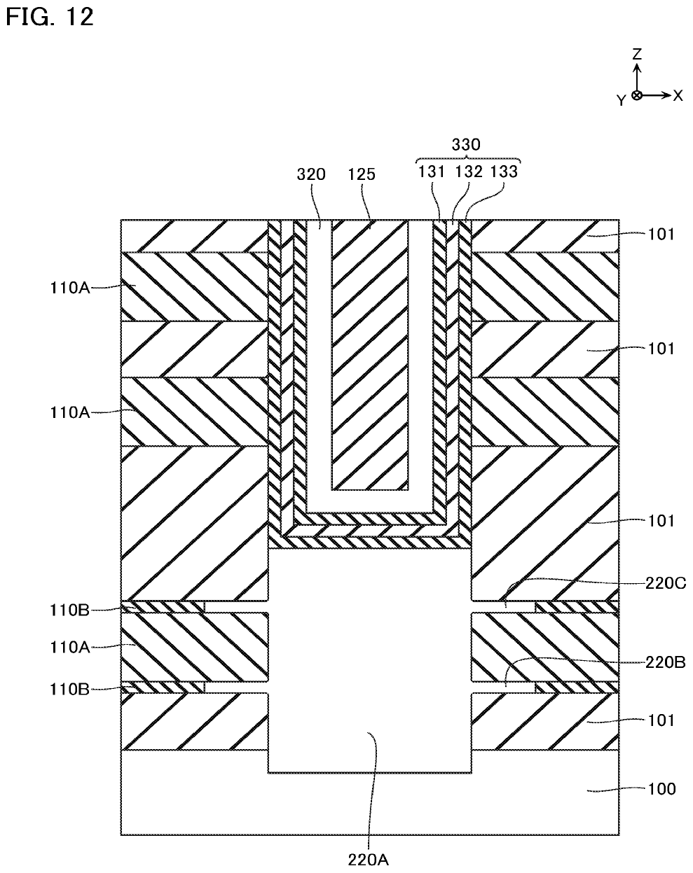

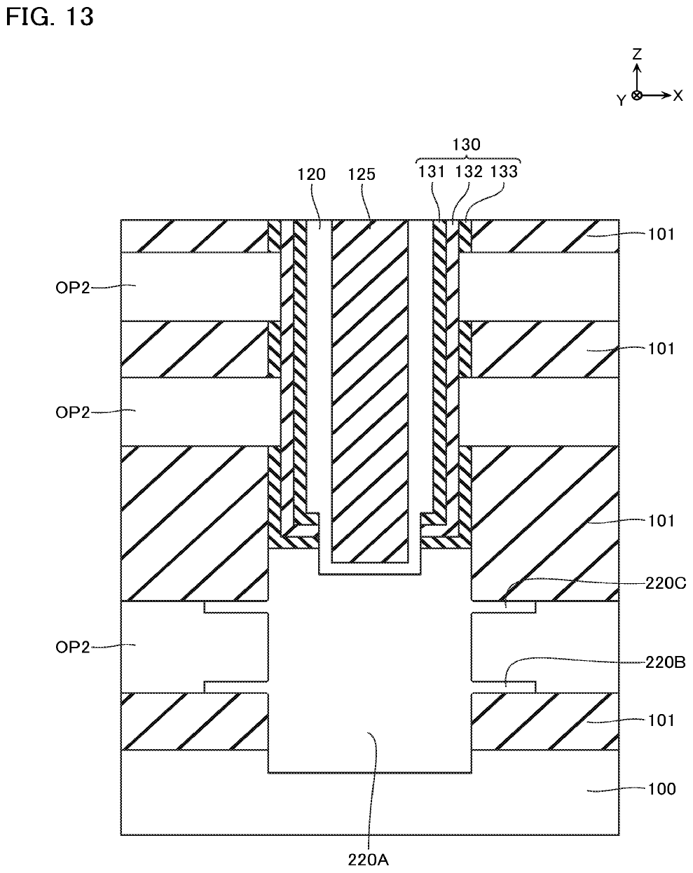

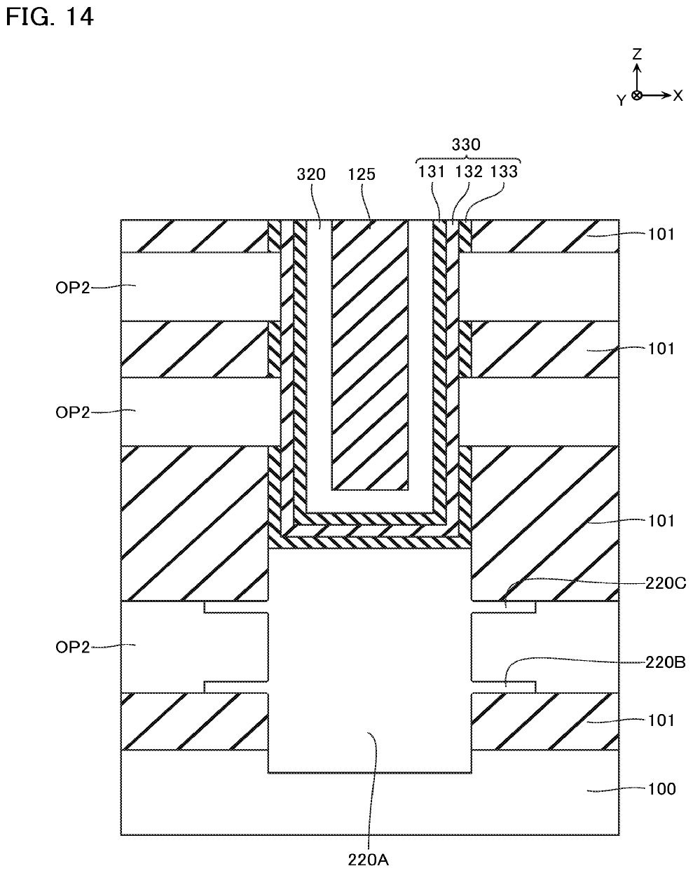

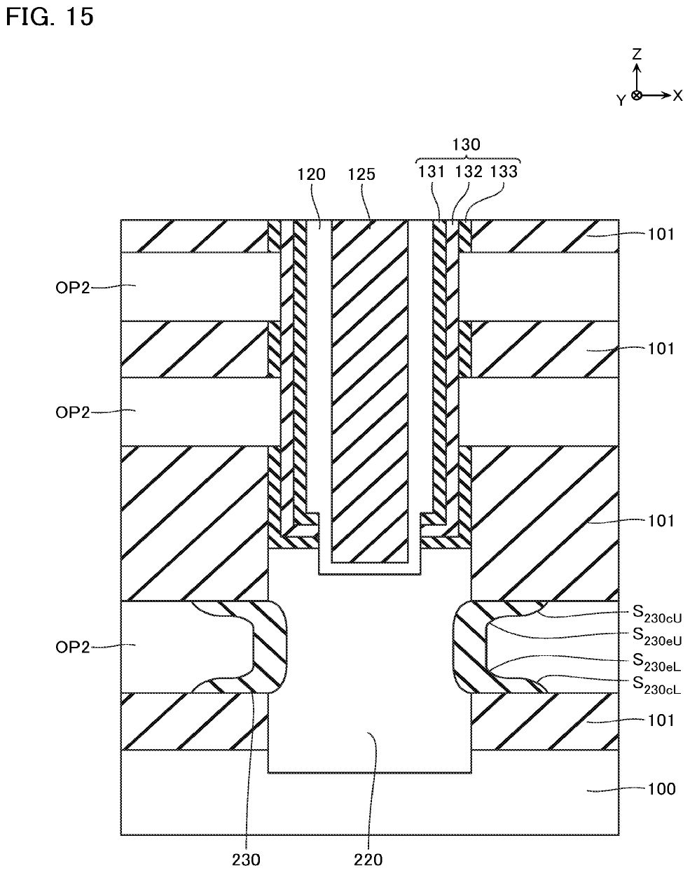

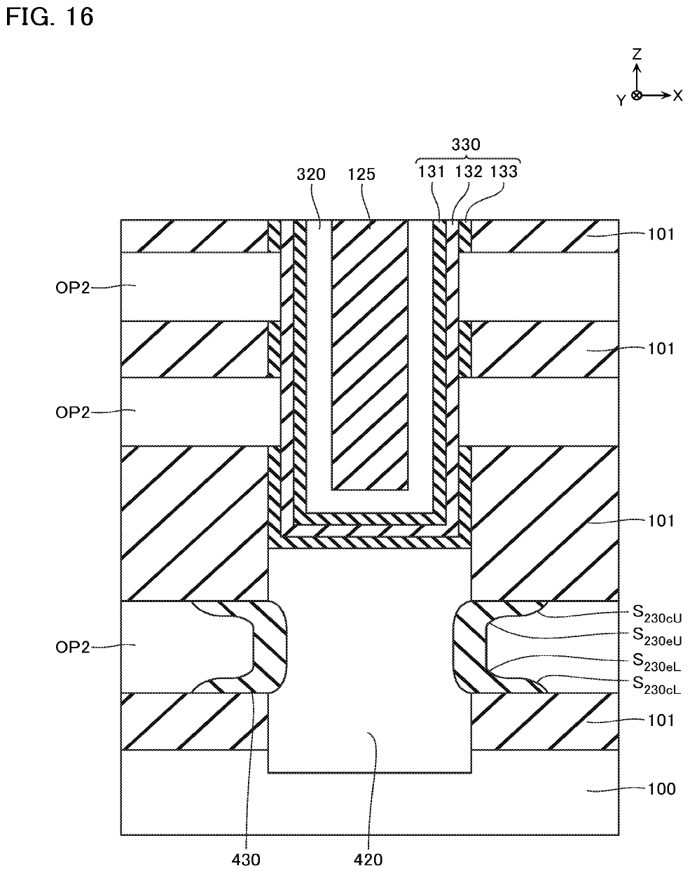

Next, with reference to FIGS. 5 to 16, the manufacturing method of the semiconductor memory device according to a first embodiment is described. FIG. 5 to FIG. 16 are schematic cross-sectional views for describing the manufacturing method. FIG. 5 to FIG. 11, FIG. 13, and FIG. 15 illustrate the cross-sectional surfaces corresponding to FIG. 3. FIG. 12, FIG. 14, and FIG. 16 illustrate the cross-sectional surfaces corresponding to FIG. 4.

In manufacturing the semiconductor memory device according to the embodiment, for example, as illustrated in FIG. 5, on the semiconductor substrate 100, the insulating layer 101, a sacrifice layer 110B, a sacrifice layer 110A, and the sacrifice layer 110B are formed. Furthermore, above the structure, a plurality of insulating layers 101 and a plurality of sacrifice layers 110A are alternately formed. The sacrifice layer 110A includes, for example, silicon nitride (SiN) or the like. The insulating layer 101 and the sacrifice layer 110B includes, for example, silicon oxide (SiO₂) or the like. The insulating layer 101 and the sacrifice layer 110A are formed, for example, by a method such as a plasma Chemical Vapor Deposition (plasma CVD). The sacrifice layer 110B is formed, for example, by a method such as Low Pressure CVD (LPCVD). Here, a wet etching rate of silicon oxide (SiO₂) formed by LPCVD may be greater than that of silicon oxide (SiO₂) formed by plasma CVD.

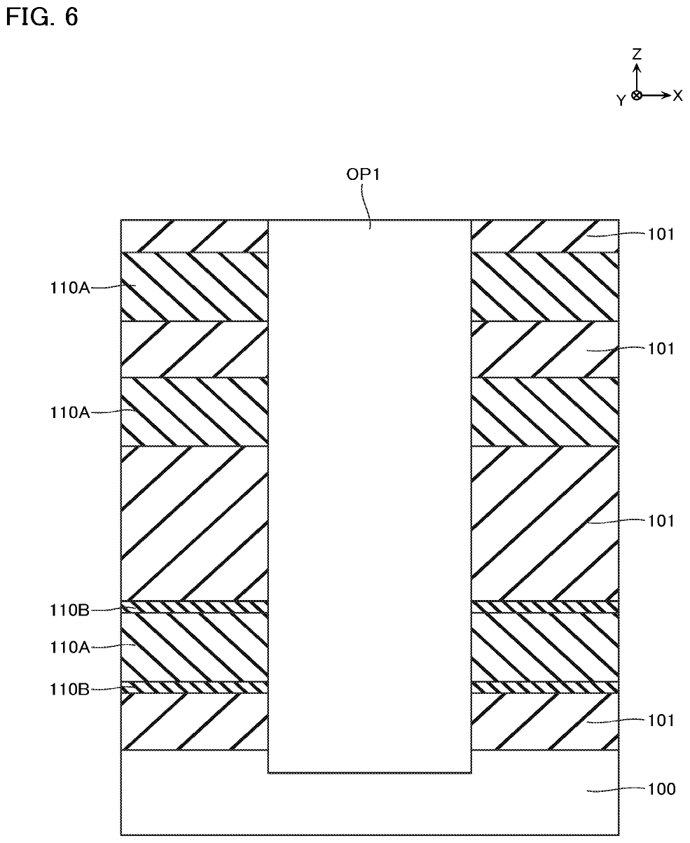

Next, for example, as illustrated in FIG. 6, openings OP1 are formed at respective positions corresponding to the plurality of semiconductor layers 120 and respective positions corresponding to the plurality of supporting structures HR. The opening OP1 is a through hole that extends in the Z direction and penetrates the insulating layers 101 and the sacrifice layers 110A and 110B, thus exposing the upper surface of the semiconductor substrate 100. This process is performed, for example, by a method such as Reactive Ion Etching (RIE).

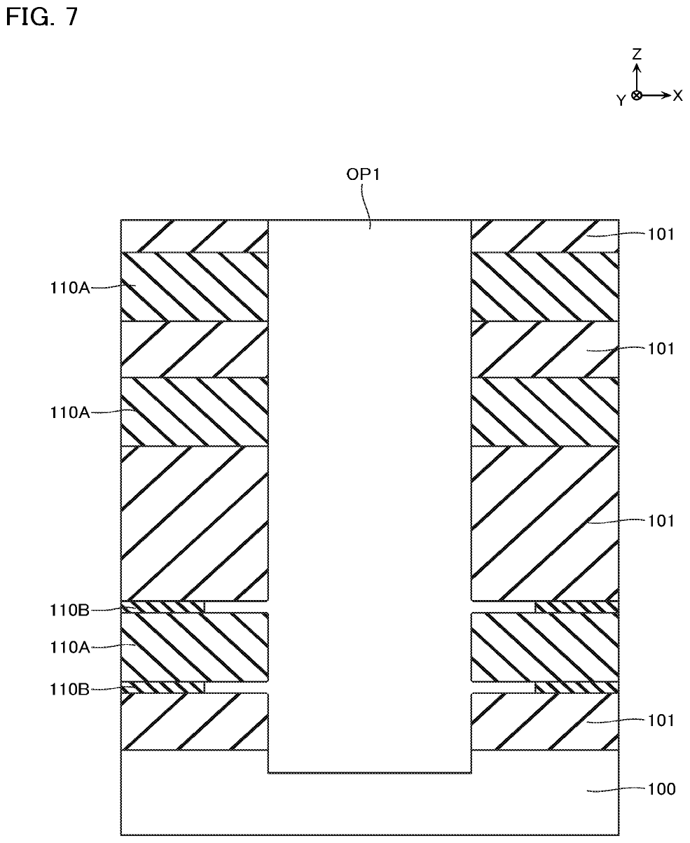

Next, for example, as illustrated in FIG. 7, the sacrifice layers 110B are partially removed via the opening OP1. This process is performed, for example, by a method such as wet etching. Thus, the upper surface of the first insulating layer 101 counted from the lower side and the lower surface of the second insulating layer 101 counted from the lower side are exposed inside the opening OP1.

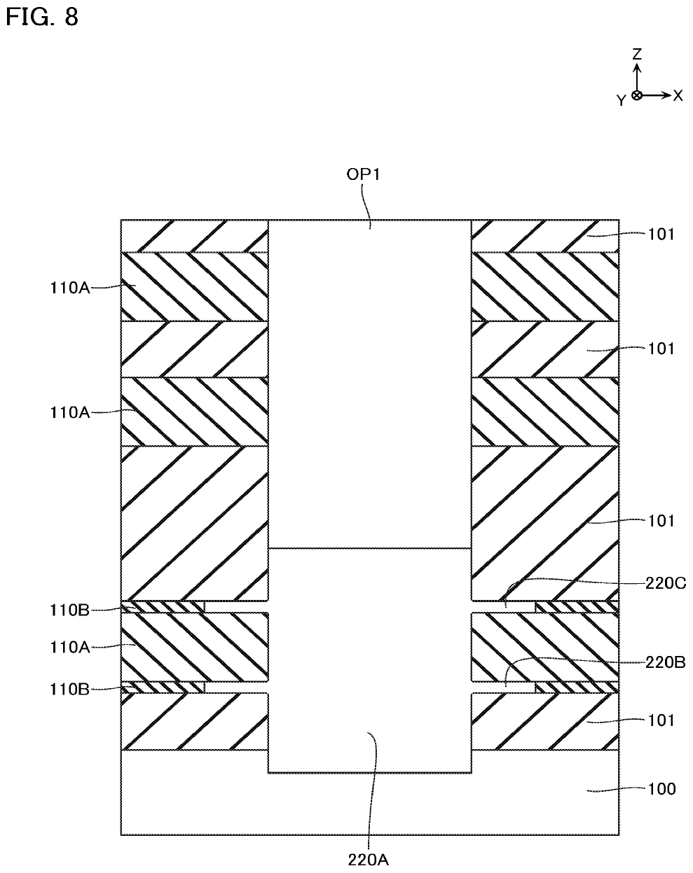

Next, for example, as illustrated in FIG. 8, an approximately cylindrically-shaped semiconductor layer 220A is formed on the bottom surface of the opening OP1. This process is performed, for example, by a method such as epitaxial growth. In this process, a semiconductor layer 220B is formed on the upper surface of the first insulating layer 101 counted from the lower side. In addition, a semiconductor layer 220C is formed on the lower surface of the second insulating layer 101 counted from the lower side. These semiconductor layers 220B and 220C are formed in an approximately annular shape and connected to an outer peripheral surface of the semiconductor layer 220A.

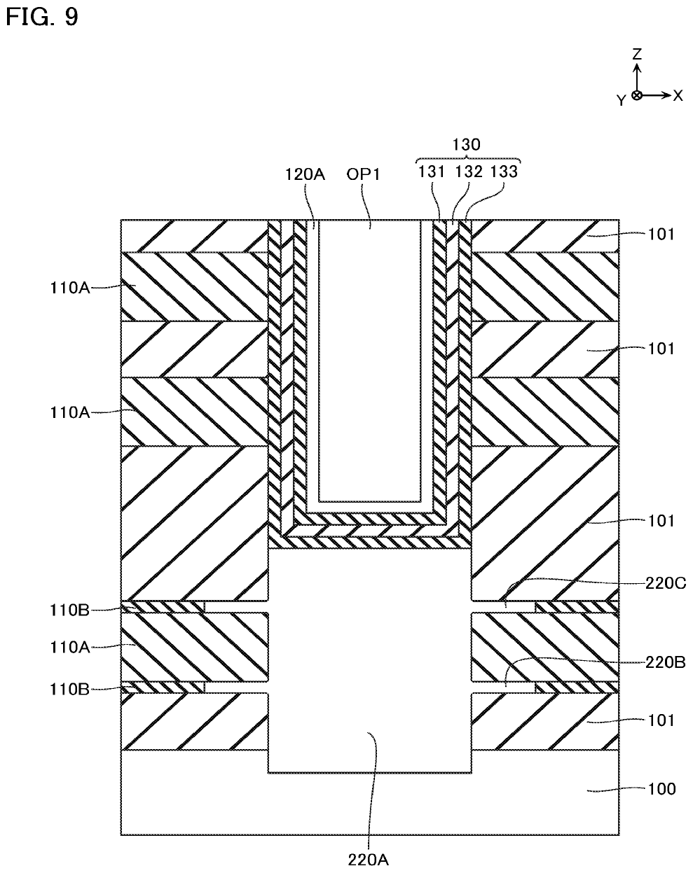

Next, for example, as illustrated in FIG. 9, the insulating layer 130 and an amorphous silicon film 120A are formed on the inner peripheral surface of the opening OP1. This process is performed, for example, by a method such as CVD.

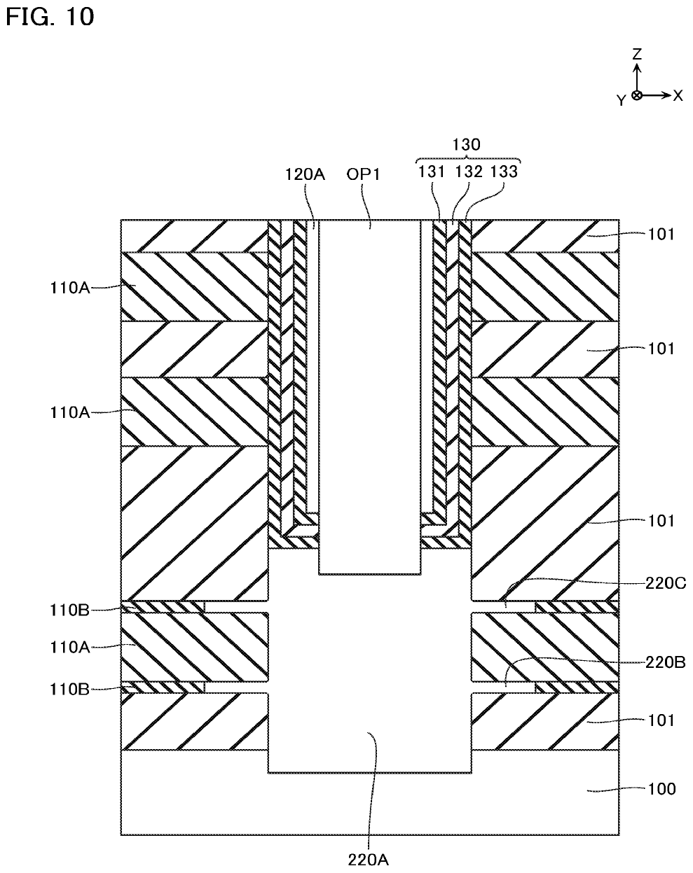

Next, for example, as illustrated in FIG. 10, portions of the insulating layer 130 and the amorphous silicon film 120A that cover the upper surface of the semiconductor layer 220A are removed. This process is performed, for example, by a method such as RIE. In addition, this process is performed on the openings OP1 corresponding to the semiconductor layer 120 of the opening OP1. The openings OP1 corresponding to the supporting structure HR may be covered by a resist or the like.

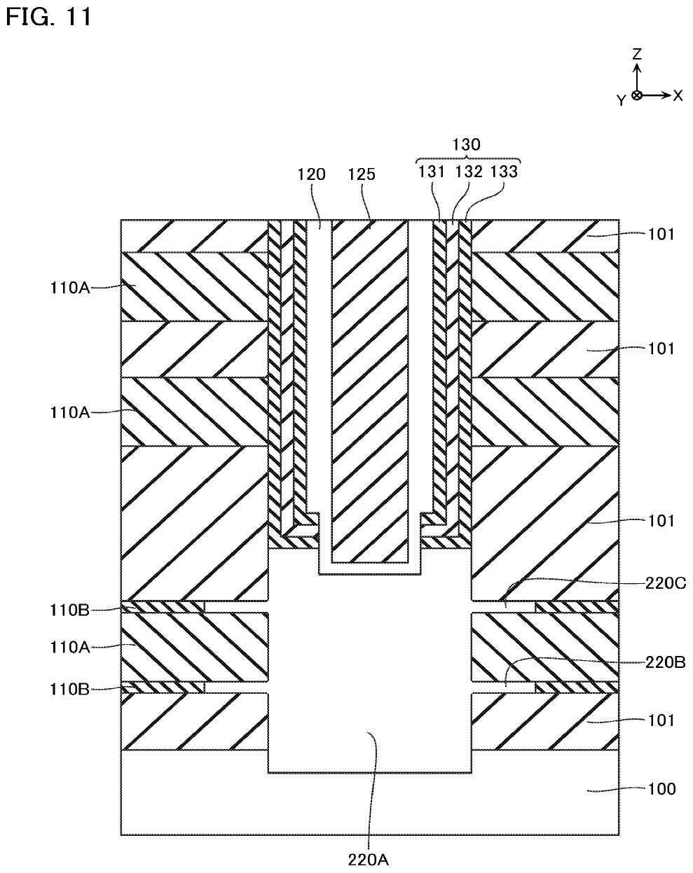

Next, for example, as illustrated in FIGS. 11 and 12, the amorphous silicon film and the insulating layer 125 are formed on upper surface of the semiconductor layer 220A and the inner peripheral surface of the amorphous silicon film 120A. This process is performed, for example, by a method such as CVD. Thus, the semiconductor layers 120 and 320 are formed.

Next, for example, as illustrated in FIGS. 13 and 14, the sacrifice layers 110A and 110B are removed. In this process, for example, a trench is formed by a method such as RIE at the position corresponding to the inter-finger insulating layer ST described with reference to FIG. 2. The sacrifice layers 110A and 110B are removed by a method such as wet etching via the trench. In FIGS. 13 and 14, cavities formed by removing the sacrifice layers 110A and 110B are illustrated as openings OP2. In this process, the insulating film 133 may be removed or is not required to be removed.

When this process is completed, the outer peripheral surface of the semiconductor layer 220A, the upper surface and the outer peripheral surface of the semiconductor layer 220B, and the lower surface and the outer peripheral surface of the semiconductor layer 220C become a state to be exposed to the openings OP2.

Next, for example, as illustrated in FIGS. 15 and 16, the insulating layers 230 and 430 are formed. This process is performed, for example, by a method such as oxidation process. In this process, the oxidation process progresses along the outer peripheral surface of the semiconductor layer 220A, the upper surface and the outer peripheral surface of the semiconductor layer 220B, and the lower surface and the outer peripheral surface of the semiconductor layer 220C. Thus, a projecting curved surface S_{230cL} is formed at a position corresponding to the outer peripheral surface of the semiconductor layer 220B. Furthermore, a recessed curved surface S_{230eL} is formed at a position corresponding to a connecting portion between the outer peripheral surface of the semiconductor layer 220A and the upper surface of the semiconductor layer 220B. In addition, a recessed curved surface S_{230eU} is formed at a position corresponding to a connecting portion between the outer peripheral surface of the semiconductor layer 220A and the lower surface of the semiconductor layer 220C. Additionally, a projecting curved surface S_{230cU} is formed at a position corresponding to the outer peripheral surface of the semiconductor layer 220C. Furthermore, in this process, the semiconductor layers 220 and 420 are formed.

Next, for example, as illustrated in FIGS. 3 and 4, the insulating layers 113 and 213, and the conductive layers 110 and 210 are formed. This process is performed, for example, by a method such as CVD. Thus, the recessed curved surface S_{210cL} is formed along the above-described projecting curved surface S_{230cL} on the lower surface of the conductive layer 210. In addition, the projecting curved surfaces S_{210eL} and S_{210eU} are formed along the above-described recessed curved surfaces S_{230eL} and S_{230eU} on opposed surfaces to the semiconductor layers 220 and 420 of the conductive layer 210. Furthermore, the recessed curved surface S_{210cU} is formed along the above-described projecting curved surface S_{230cU} on the upper surface of the conductive layer 210.

Subsequently, the wiring or the like is formed, and the wafer is separated by dicing, and thus the semiconductor memory device according to the first embodiment is formed.

### Comparative Example

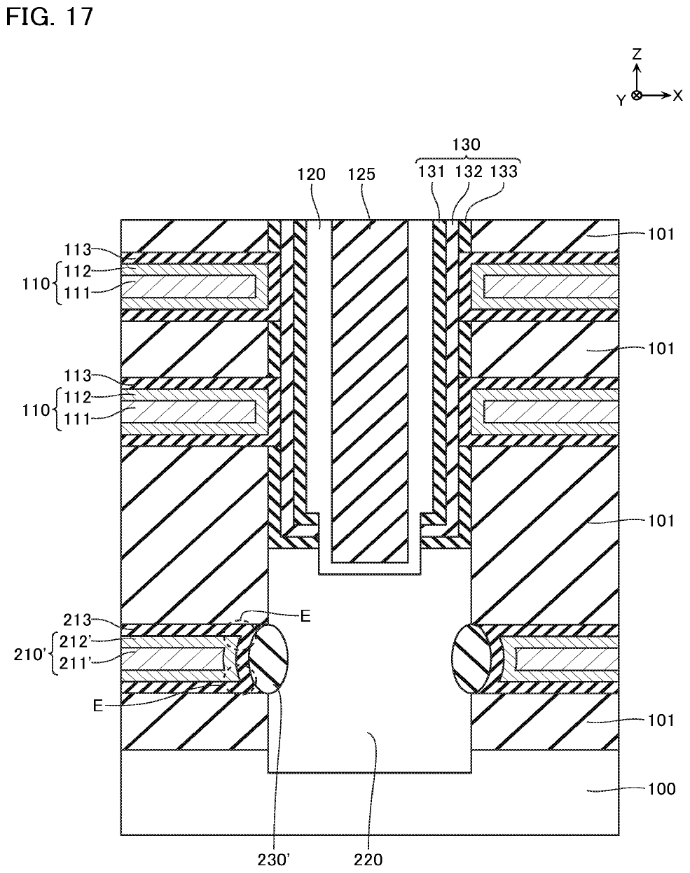

FIG. 17 is a schematic cross-sectional view illustrating a part of configuration of a semiconductor memory device according to the comparative example. The semiconductor memory device according to the comparative example includes a conductive layer 210′ and an insulating layer 230′, not the conductive layer 210 and the insulating layer 230. The conductive layer 210′ includes a metal film 211′ of tungsten (W) or the like and a barrier conductive film 212′ of titanium nitride (TiN) or the like that covers an upper surface and a lower surface and side surfaces in the X direction and the Y direction of the metal film 211′. The conductive layer 210′ does not include the part 210n as illustrated in FIG. 3. A thickness in the Z direction of the conductive layer 210′ is approximately uniform. The insulating layer 230′ does not cover the upper surface and the lower surface of the conductive layer 210′.

In manufacturing the semiconductor memory device according to the comparative example, the sacrifice layer 110B is not formed in the process described with reference to FIG. 5. Furthermore, in manufacturing the semiconductor memory device according to the comparative example, the process described with reference to FIG. 7 is not executed and the semiconductor layers 220B and 220C are not formed in the process described with reference to FIG. 8.

In manufacturing the semiconductor memory device according to the comparative example, an insulating layer 230′ as illustrated in FIG. 17 is formed when the processes described with reference to FIGS. 15 and 16 are executed. In this process, the oxidation process progresses along the outer peripheral surface of the semiconductor layer 220A. In such case, projecting curved surfaces are sometimes formed on an inner peripheral surface and an outer peripheral surface of the insulating layer 230′.

In manufacturing the semiconductor memory device according to the comparative example, when the conductive layer 210′ is formed, for example, as illustrated in FIG. 17, a recessed curved surface is sometimes formed on the opposed surface to the semiconductor layer 220 of the conductive layer 210′, along the projecting curved surface on the outer peripheral surface of the insulating layer 230′. Thus, a corner portion E is sometimes formed between the recessed curved surface and the upper surface of the conductive layer 210′. Similarly, the corner portion E is sometimes formed between the recessed curved surface and the lower surface of the conductive layer 210′. In such configuration, when a voltage is supplied to the conductive layer 210′, an electric field is converged at the corner portions E and dielectric breakdown is likely to occur between the conductive layer 210′ and the semiconductor layer 220.

[Effect of First Embodiment]

As described with reference to FIG. 3 or the like, in the semiconductor memory device according to the first embodiment, the projecting curved surfaces S_{210eL} and S_{210eU} are formed on the opposed surface to the semiconductor layers 220 and 420 of the conductive layer 210. Such a structure ensures reducing convergence of electric field as described above and thus reducing occurrence of dielectric breakdown.

As described with reference to FIG. 3 or the like, in the semiconductor memory device according to the first embodiment, the recessed curved surface S_{210cL} is formed on the lower surface of the conductive layer 210, and the recessed curved surface S_{210cU} is formed on the upper surface of the conductive layer 210. Here, a corner portion is likely to be formed at the connecting portion between the recessed curved surface S_{210cL} and the lower surface S_{210fL}. In addition, a corner portion is likely to be formed at the connecting portion between the recessed curved surface S_{210cU} and the upper surface S_{210fU}. However, such portions have comparatively large distances from the semiconductor layer 220. Therefore, the semiconductor memory device according to the first embodiment ensures reducing occurrence of dielectric breakdown.

### Another Embodiment

The semiconductor memory device according to the first embodiment has been described above. However, the semiconductor memory device according to this embodiment is merely an example, and a specific configuration, a specific manufacturing method, and the like are adjustable, as necessary.

For example, in the semiconductor memory device according to the first embodiment, the semiconductor layers 220 and 420 are connected to the semiconductor substrate 100 containing single-crystal silicon (Si). However, such a configuration is merely an example, a specific configuration is adjustable, as necessary.

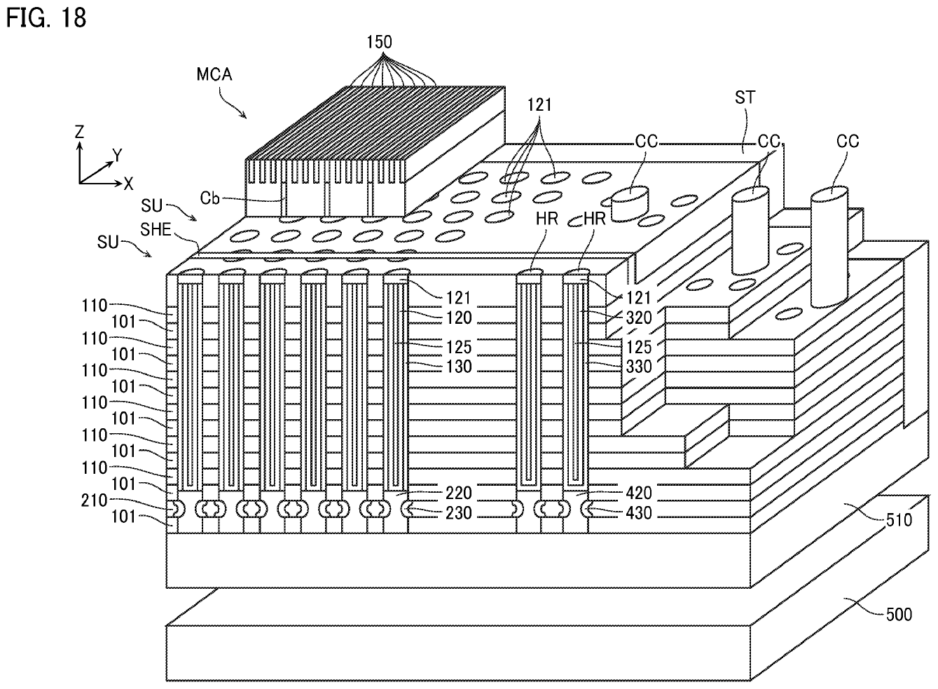

For example, a semiconductor memory device illustrated in FIG. 18 is basically configured similarly to the semiconductor memory device according to the first embodiment. FIG. 18 is a schematic perspective view illustrating a part of the configuration of the semiconductor memory device according to another embodiment. However, the semiconductor memory device illustrated in FIG. 18 includes a semiconductor substrate 500 and a semiconductor layer 510, instead of the semiconductor substrate 100. The semiconductor substrate 500 is basically configured similarly to the semiconductor substrate 100. However, the semiconductor substrate 500 is not connected to the semiconductor layers 220 and 420. The semiconductor layer 510 is connected to the semiconductor layers 220 and 420 and functions as at least apart of the source line SL (FIG. 1). The semiconductor layer 510 is, for example, a semiconductor layer of silicon (Si) containing impurities such as phosphorus (P) or boron (B), or the like. The semiconductor layer 510 may include single-crystal silicon and may include polycrystalline silicon. On a lower surface of the semiconductor layer 510, a metal layer of tungsten (W) or the like, or a conductive layer of tungsten silicide or the like may be disposed. In such case, the semiconductor layer 510, and the metal layer or the conductive layer, each configure a part of the source line SL (FIG. 1).

Furthermore, in any of the structures described above, a structure as described with reference to FIG. 5 may remain in any of the regions of the semiconductor substrates 100 and 500. In this case, the thickness in the Z direction of the sacrifice layer 110A disposed at the lowermost layer may be smaller than the thickness T_{210f} (FIG. 3) in the Z direction of the part 210f of the conductive layer 210 and may be larger than the thickness T₂₁₀ₙ (FIG. 3) in the Z direction of the part 210n.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of first conductive layers arranged in a first direction, the plurality of first conductive layers extending in a second direction intersecting with the first direction;
a first semiconductor layer extending in the first direction and being opposed to the plurality of first conductive layers;
a first insulating film disposed between the plurality of first conductive layers and the first semiconductor layer, the first insulating film including an electric charge accumulating portion;
a second semiconductor layer connected to one end in the first direction of the first semiconductor layer;
a second conductive layer extending in the second direction and being opposed to the second semiconductor layer;
a second insulating film disposed between the second conductive layer and the second semiconductor layer; and
a third semiconductor layer extending in the second direction and being connected to the first semiconductor layer via the second semiconductor layer, wherein
the second conductive layer includes:
a first part extending in the second direction; and
a second part disposed between the first part and the second semiconductor layer, and
when a thickness in the first direction of the first part is assumed to be a first thickness, and a thickness in the first direction of the second part is assumed to be a second thickness,
the second thickness is smaller than the first thickness.

2. The semiconductor memory device according to claim 1, wherein
when, in one of the plurality of first conductive layers,
a part disposed at a position aligned in the first direction with the first part is assumed to be a third part,
a part disposed at a position aligned in the first direction with the second part is assumed to be a fourth part,
a thickness in the first direction of the third part is assumed to be a third thickness, and
a thickness in the first direction of the fourth part is assumed to be a fourth thickness,
a difference between the first thickness and the second thickness is larger than a difference between the third thickness and the fourth thickness.

3. The semiconductor memory device according to claim 1, wherein
when a surface on a side of the plurality of first conductive layers in the first direction of the first part is assumed to be a first surface,
a surface on the opposite side to the plurality of first conductive layers in the first direction of the first part is assumed to be a second surface,
a surface on a side of the plurality of first conductive layers in the first direction of the second part is assumed to be a third surface, and
a surface on the opposite side to the plurality of first conductive layers in the first direction of the second part is assumed to be a fourth surface,
the third surface is farther from the plurality of first conductive layers than the first surface,
the fourth surface is closer to the plurality of first conductive layers than the second surface.

4. The semiconductor memory device according to claim 3, wherein
when, in one of the plurality of first conductive layers:
a part disposed at a position aligned in the first direction with the first part is assumed to be a third part; and
a part disposed at a position aligned in the first direction with the second part is assumed to be a fourth part; and
when a surface on a side of the second conductive layer in the first direction of the third part is assumed to be a fifth surface,
a surface on the opposite side to the second conductive layer in the first direction of the third part is assumed to be a sixth surface,
a surface on a side of the second conductive layer in the first direction of the fourth part is assumed to be a seventh surface, and
a surface on the opposite side to the second conductive layer in the first direction of the fourth part is assumed to be an eighth surface,
a distance in the first direction between the first surface and the third surface is larger than a distance in the first direction between the sixth surface and the eighth surface, and
a distance in the first direction between the second surface and the fourth surface is larger than a distance in the first direction between the fifth surface and the seventh surface.

5. The semiconductor memory device according to claim 4, wherein
when the one of the plurality of first conductive layers is a first conductive layer closest to the second conductive layer among the plurality of first conductive layers,
two of the plurality of first conductive layers neighboring in the first direction are assumed to be a lower conductive layer and an upper conductive layer respectively, and
when a surface in the first direction of the lower conductive layer opposed to the upper conductive layer is assumed to be a ninth surface, and
a surface in the first direction of the upper conductive layer opposed to the lower conductive layer is assumed to be a tenth surface,
a distance in the first direction between the first surface and the fifth surface is larger than a distance in the first direction between the ninth surface and the tenth surface.

6. The semiconductor memory device according to claim 3, wherein
the third surface and the fourth surface are connected one another via a projecting curved surface in at least a part between the third surface and the fourth surface.

7. The semiconductor memory device according to claim 3, wherein
a recessed first curved surface is disposed between the first surface and the third surface, and
a recessed second curved surface is disposed between the second surface and the fourth surface.

8. The semiconductor memory device according to claim 7, wherein
the third surface is continuous with the first curved surface, and
the fourth surface is continuous with the second curved surface.

9. The semiconductor memory device according to claim 1, wherein
the first insulating film extends in the first direction along an outer peripheral surface of the first semiconductor layer, and
the second semiconductor layer is disposed between an end portion on a side of the third semiconductor layer in the first direction of the first insulating film and the third semiconductor layer.

10. The semiconductor memory device according to claim 1, wherein
when, in the second semiconductor layer:
a width in the second direction of a portion connected to the first semiconductor layer is assumed to be a first width;
a width in the second direction of a portion opposed to the second conductive layer is assumed to be a second width; and
a width in the second direction of a portion connected to the third semiconductor layer is assumed to be a third width,
the second width is smaller than the first width and smaller than the third width.

11. The semiconductor memory device according to claim 1, wherein
a distance in the second direction between the second conductive layer and the second semiconductor layer is larger than a distance in the second direction between at least one of the plurality of first conductive layers and the first semiconductor layer.

12. The semiconductor memory device according to claim 1, wherein
the third semiconductor layer is a part of a substrate.

13. The semiconductor memory device according to claim 12, wherein
the second semiconductor layer and the third semiconductor layer include a single crystal, and
an orientation face of the crystal included in the second semiconductor layer is aligned with an orientation face of the crystal included in the third semiconductor layer.

14. The semiconductor memory device according to claim 1, wherein
the third semiconductor layer is at least a part of a source layer disposed apart from a substrate in the first direction.

15. The semiconductor memory device according to claim 1, wherein
a first region of a substrate is disposed with:
the plurality of first conductive layers;
the first semiconductor layer;
the first insulating film;
the second semiconductor layer;
the second conductive layer; and
the second insulating film,
a second region different from the first region of the substrate is disposed with:
a plurality of first layers arranged in the first direction corresponding to the plurality of first conductive layers, the plurality of first layers extending in the second direction; and
a second layer extending in the second direction and being disposed at a position corresponding to the second conductive layer in the first direction, and
when a thickness in the first direction of the second layer is assumed to be a fifth thickness,
the fifth thickness is smaller than the first thickness and larger than the second thickness.

16. A semiconductor memory device comprising:
a substrate including a first region and a second region, in which,
the first region includes:
a plurality of first conductive layers arranged in a first direction intersecting with a surface of the substrate, the plurality of first conductive layers extending in a second direction intersecting with the first direction;
a first semiconductor layer extending in the first direction and being opposed to the plurality of first conductive layers;
a first insulating film disposed between the plurality of first conductive layers and the first semiconductor layer, the first insulating film including an electric charge accumulating portion;
a second semiconductor layer connected to one end in the first direction of the first semiconductor layer;
a second conductive layer extending in the second direction and being opposed to the second semiconductor layer;
a second insulating film disposed between the second conductive layer and the second semiconductor layer; and
a third semiconductor layer extending in the second direction and being connected to the first semiconductor layer via the second semiconductor layer, and
the second region includes:
a plurality of first layers arranged in the first direction corresponding to the plurality of first conductive layers, the plurality of first layers extending in the second direction; and
a second layer extending in the second direction and being disposed at a position corresponding to the second conductive layer in the first direction, wherein
the second conductive layer includes:
a first part extending in the second direction; and
a second part disposed between the first part and the second semiconductor layer, and
when a thickness in the first direction of the first part is assumed to be a first thickness,
a thickness in the first direction of the second layer is smaller than the first thickness.

17. The semiconductor memory device according to claim 16, wherein
the second layer includes silicon nitride.

18. The semiconductor memory device according to claim 16, wherein
the first insulating film extends in the first direction along an outer peripheral surface of the first semiconductor layer, and
the second semiconductor layer is disposed between an end portion on a side of the third semiconductor layer in the first direction of the first insulating film and the third semiconductor layer.

19. The semiconductor memory device according to claim 16, wherein
a distance in the second direction between the second conductive layer and the second semiconductor layer is larger than a distance in the second direction between at least one of the plurality of first conductive layers and the first semiconductor layer.

20. The semiconductor memory device according to claim 16, wherein
when a thickness in the first direction of the second part is assumed to be a second thickness, the thickness in the first direction of the second layer is larger than the second thickness.
